(19) United States
(12) Patent Application Publication
(10) Pub. No.: US 2016/0135294 A1
(43) Pub. Date: May 12, 2016

(54) PREPREG AND METHOD FOR MANUFACTURING THE SAME

(71) Applicant: SAMSUNG ELECTRO-MECHANICS CO., LTD., Suwon-si (KR)

(72) Inventors: Eun-Sil KIM, Hwaseong-si (KR); Sang-Hyun SHIN, Suwon-si (KR)

(73) Assignee: SAMSUNG ELECTRO-MECHANICS CO., LTD., Suwon-si (KR)

(21) Appl. No.: 14/932,700

(22) Filed: Nov. 4, 2015

(30) Foreign Application Priority Data
Nov. 7, 2014 (KR) 10-2014-0154420

(51) Int. Cl. H05K 1/03; H05K 3/00; H05K 1/02

(52) U.S. Cl. CPC H05K 1/0366; H05K 1/0373; H05K 1/0278; H05K 3/0064; H05K 2201/0191; H05K 2201/0209; H05K 2201/068; H05K 2201/0195

(57) ABSTRACT

A prepreg includes: a core material having a first resin material impregnated therein; and second resin materials laminated above and below the core material and including a non-linear joint interface formed with the first resin material.

### CROSS-REFERENCE TO RELATED APPLICATION(S)

This application claims the benefit of Korean Patent Application No. 10-2014-0154420, filed in the Korean Intellectual Property Office on Nov. 7, 2014, the entire disclosure of which is incorporated herein by reference for all purposes.

### BACKGROUND

1. Field

The following description relates to prepreg having high functionality and a method of manufacturing the same.

2. Description of Related Art

With the growing advancement of the manufacturing technology of electronic devices, it has been increasingly required that printed circuit boards embedded essentially in the electronic devices be lighter, thinner and smaller. As wiring layers for connecting circuits and insulation layers for interlayer insulation are laminated alternately in the printed circuit board, the wiring layers are usually made of a metallic material, for example, copper, and the insulation layers are made of polymer resin, for example, resin or epoxy.

The insulation layers need to be made thin in order to make the printed circuit board thinner, however it is more difficult it is to control a warpage problem of the printed circuit board as the insulation layers are made thinner. That is, since it is more difficult for the insulation layers, in comparison to the metallic wiring layers, to control the properties of low coefficient of thermal expansion (CTE), high glass transition temperature and high modulus, the insulation layers have deteriorated electrical, thermal and mechanical properties.

Moreover, the printed circuit board, which includes a number of electronic components mounted thereon, has multiple insulation layers laminated thereon in order to design a variety of wiring patterns, and thus requires a highly functional prepreg in order to form fine wiring patterns and provide electrical insulation between adjacent wires. An example of a prepreg is disclosed in Published Japanese Patent Application 2012-054323.

In general, the pregreg is formed in a plate shape in which an organic material such as epoxy is impregnated in a core material that is constructed of a woven type of glass cloth or fabric cloth. The prepreg may be used for an insulation layer of a copper clad laminate (CCL) as well as a center core or an outermost insulation layer of a multilayered printed circuit board. While an inorganic material such as epoxy is impregnated in the core material, the prepreg may have an inorganic filler additionally included in the organic material.

Although it may be possible to maintain a low CTE by having the inorganic filler impregnated in the prepreg, the inorganic filler may protrude on a surface of the prepreg, possibly causing a deteriorated cohesion with the wiring when the wiring is formed on the prepreg, and restricting the formation of fine wiring patterns due to an increased roughness after a desmear process when the fine wiring patterns are formed by a SAP method.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a prepreg includes: a core material including a first resin material impregnated therein; and second resin materials laminated above and below the core material and including a non-linear joint interface formed with the first resin material.

The core material may include a bent portion, and the first resin material may be hardened along the bent portion such that an upper surface and a lower surface of the core material are formed as bent surfaces.

The core material may include fabric cloth or glass cloth.

The first resin material may include an inorganic filler.

The second resin materials may be formed in a same thickness above and below the core material, and may have same material properties.

According to another general aspect, a prepreg includes: a core material having a first resin material impregnated therein; a second resin material laminated above the core material; and a third resin material laminated below the core material, wherein at least one of the second resin material or the third resin material forms a non-linear joint interface at a surface joined with the first resin material.

The core material may include a bent portion formed thereon, and the first resin material may be hardened along the bent portion such that an upper surface and a lower surface of the core material are formed as bent surfaces.

The first resin material may include an inorganic filler.

The second resin material and the third resin material may have different material properties and different coefficients of thermal expansion from each other.

The second resin material or the third resin material may have same material properties as material properties of the first resin material and a same coefficient of thermal expansion as a coefficient of thermal expansion of the first resin material.

The second resin material and the third resin material may have a same thickness.

The second resin material and the third resin material may have different thicknesses from each other.

The second resin material may be thinner than the third resin material.

A circuit may be formed on a surface of the second resin material, and a buried circuit pattern may be formed on the third resin material.

The third resin material may be thinner than the second resin material.

A circuit may be formed on a surface of the third resin material, and a buried circuit pattern may be formed on the second resin material.

According to another general aspect, method of manufacturing a prepreg includes: preparing a core material including fabric cloth or glass cloth; applying a first resin material to cover a bent portion of the core material; hardening the first resin material such that the first resin material forms a bent surface along the bent portion of the core material; laminating a second resin material and a third resin material, respectively, above and below the core material; and thermos-compressing the second resin material and the third resin material such that a non-linear joint interface is formed at a joint surface between the first resin material and at least one of the second resin material or the third resin material.

In the hardening of the first resin material, the first resin material may be semi-hardened or full-hardened.

The laminating of the second resin material and the third resin material may include applying the second resin material and the third resin material on respective cover films and maintaining the second resin material and the third resin material in a semi-hardened state.

The second resin material and the third resin material may have different material properties and different coefficients of thermal expansion from each other, and the laminating of the second resin material and the third resin material may include laminating the second resin material and the third resin material in a same thickness.

the second resin material and the third resin material may have different material properties and different coefficients of thermal expansion from each other, and the laminating of the second resin material and the third resin material may include laminating the second resin material and the third resin material in different thicknesses from each other.

The thickness of the third resin material may be less than the thickness of the second resin material.

The thickness of the second resin material may be less than the thickness of the third resin material.

Other features and aspects will be apparent from the following detailed description, the drawings, and the claims.

### BRIEF DESCRIPTION OF THE DRAWINGS

FIG. 1 is a cross-sectional view of a prepreg according to an example.

FIG. 2 is a cross-sectional view of a prepreg according to another example.

FIGS. 3A-3D show example processes of a method of manufacturing a prepreg, wherein FIGS. 3A and 3B are cross-sectional views showing a core material, FIG. 3C is a cross-sectional view showing a resin material laminated above and below the core material, and FIG. 3D is a cross-sectional view showing the prepreg in which the resin material is laminated above and below the core material.

FIGS. 4 and 5 show example processes of another method of manufacturing a prepreg, wherein FIG. 4 shows a process in which a second resin material laminated on a core material is thinner than a third resin material, and FIG. 5 shows a process in which the third resin material laminated on the core material is thinner than the second resin material.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

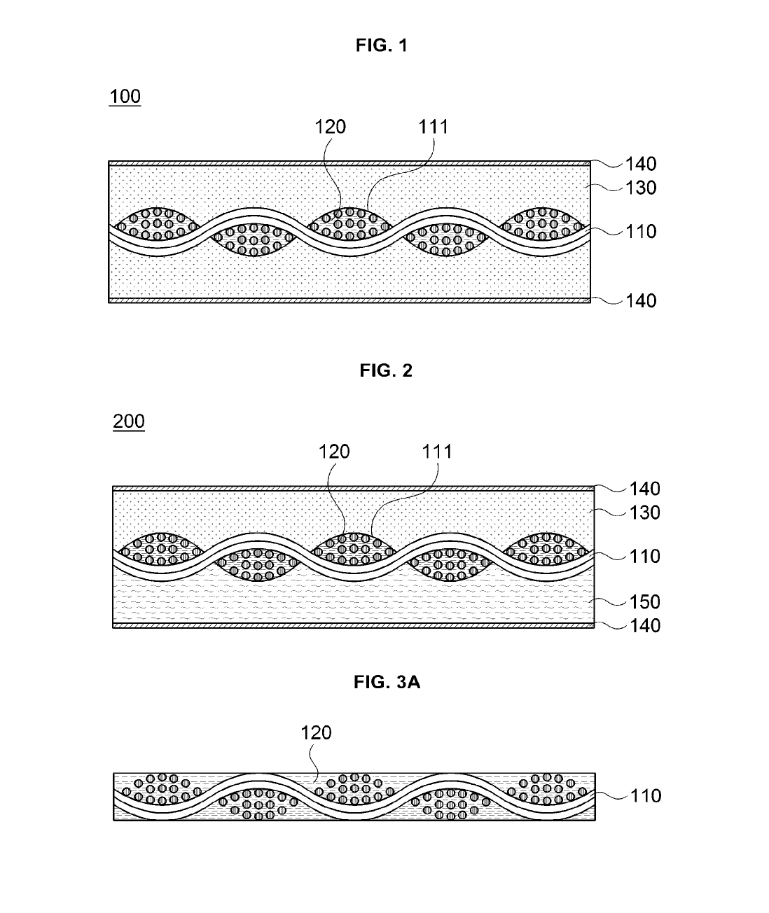

FIG. 1 is a cross-sectional view showing a prepreg 100 according to an example.

As illustrated in FIG. 1, the prepreg 100 includes a core material 110 in which a first resin material 120 is impregnated, and a second resin material 130 that is laminated above and below the core material 110. A cover film 140, which is made of an insulation material or a copper foil may be additionally laminated on outside surfaces of the second resin material 130.

The core material 110, which may be made of fabric cloth or glass cloth, for example, has a woven structure in which 1 to 3 rows of fabric or glass filaments are crossed with each other and thus has a higher modulus than a resin material. Accordingly, when heat and pressure are applied while the resin material is laminated, any occurrence of warpage in the prepreg 100 is minimized.

The core material 110 has bent portions or protruding portions 111 formed therein according to an arrangement of the fabric or glass filaments at locations where the fabric or glass filaments overlap in a criss-cross pattern. A height of the bent portions 111 may vary according to the number and arrangement of the fabric or glass filaments, and may be generally greater if there is a greater number of filaments. That is, at an overlapping location of the fabric or glass filaments, the fabric or glass filaments are bulged out, and the rest of the locations of the core material 110 are relatively concaved in.

The core material 110 has the first resin material 120 impregnated therein, and the first resin material 120 is hardened along the bent portions 111 of the core material 110. Accordingly, when the core material 110 is viewed from above, an upper surface and a lower surface of the core material 110 in which the first resin material 120 is impregnated are each formed as a non-linear bent surface. By having the first resin material 120 impregnated therein so as to cover upper and lower parts of the bent portions 111 and then being thermally cured, the core material 110 having the first resin material 120 impregnated therein allows the first resin material 120 to be also formed as non-linear bent surfaces along the bent portions 111.

The first resin material 120 impregnated in the core material 110 is made of an organic material such as epoxy or resin, and as the first resin material 120 is impregnated compactly in spaces between the fabric or glass filaments and then cured, the core material 110 may be formed to have a high modulus. The first resin material 120 is not limited to the resin material such as epoxy or resin, and any thermosetting resin may be introduced to the first resin material 120 as long as it is an organic material that is capable of being impregnated between the fabric or glass filaments.

A second resin material 130 is laminated above and below the core material 110 having the first resin material 120 impregnated therein. The second resin material 130 may be made of a same resin material above and below the core material 110 and formed to have a same thickness above and below the core material 110. The second resin material 130 is made of a thermosetting resin or a UV curing resin. A urea resin, melamine resin, bismaleimide resin, polyurethane resin, benzoxazine resin, cyanate ester resin, bisphenol-S epoxy resin, bisphenol-F epoxy resin or copolymer epoxy resin of bisphenol-S and bisphenol-F may be used for a thermosetting resin. However, the disclosure is not limited to the thermosetting resin described herein and may be implemented with any known resin as long as it has a thermosetting property.

Moreover, acrylic resin may be used for a UV curing resin, but the disclosure is not limited to the UV curing resin described herein and may be implemented with any known resin as long as it has a UV curing property.

Although it will be described later in greater detail when a method of manufacturing a prepreg is described, the second resin material 130 is coated on the cover film 140 and then is laminated above and below the core material 110 while the second resin material 130 coated on the cover film 140 is in a semi-cured state (i.e., B-stage). Then, the laminated second resin material 130 is heated and compressed to be cured to a predetermined thickness, allowing the second resin material 130 to be laminated in such a way that one surface thereof is tightly adhered to the core material 110 in which the first resin material 120 is impregnated.

Here, the first resin material 120 impregnated in the core material 110 and the second resin material 130 are joined with each other by forming a non-linear joint interface along the bent portions 111 of the core material 110.

Accordingly, by forming the first resin material 120 with a thermosetting resin having a high modulus when cured completely, and by having the first resin material 120 compactly impregnated and cured in the core material 110, the prepreg 100 allows the core material 110 having the first core material 120 impregnated therein to function as a core of the prepreg 100. Thus, the prepreg 100 is manufactured in a thin form but still has a low coefficient of thermal expansion and a high thermal conductivity. Moreover, the prepreg 100 has an enhanced rigidity because the upper and lower surfaces of the core material 110 in which the first resin material 120 is cured are formed in the shape of non-linear bent surfaces.

In the prepreg 100, a large quantity of inorganic filler may be further contained in the core material 110 having the first resin material 120 impregnated therein. The reason why the first resin material 120 may additionally contain the inorganic filler is that the core material 110 may be vulnerable to thermal deformation because the core material 110 will have a higher coefficient of thermal expansion despite the rigidity being enhanced by the cured resin if the core material 110 has the first resin material 120, which is a thermosetting or UV curing resin, impregnated therein only. Accordingly, by lowering the coefficient of thermal expansion by having the inorganic filler contained in the first resin material 120, warpage deformation may be minimized when thermal compression is applied.

FIG. 2 is a cross-sectional view of a prepreg 200 according to another example.

In FIG. 2, any element that is the same as an element of the example illustrated in and described with reference to FIG. 1 is referenced with the same reference numeral and will not be redundantly described herein.

As illustrated in FIG. 2, the prepreg 200 includes a core material 110 in which a first resin material 120 is impregnated, and a second resin material 130 and a third resin material 150 which are laminated, respectively, above and below the core material 110.

The second resin material 130 and the third resin material 150 are made of respective resins having different material properties from one another. That is, the second resin material 130 and the third resin material 150 may each be made of a thermosetting resin or a UV curing resin, and the thermosetting resin or UV curing resin of the second resin material may have a different coefficient of thermal expansion than the thermosetting resin or UV curing resin of the third resin material.

Since the second resin material 130 and the third resin material 150 are made of respective resins having different coefficients of thermal expansion, the second resin material 130 and the third resin material 150 may be disposed such that warpage occurs in a same direction or in opposite directions when the second resin material 130 and the third resin material 150 are laminated, respectively, above and below the core material 110. Accordingly, it is possible to control the overall direction of warpage of the prepreg 200. Moreover, the second resin material 130 and the third resin material 150 may be made of respective resins generally having same material properties but different coefficients of thermal expansion causing warpage in an opposite direction from each other.

The core material 110 may be made of fabric cloth or glass cloth in which fabric or glass filaments are woven by crossing with each other. By having the first resin material 120 impregnated in the core material 110, an upper surface and a lower surface of the core material 110 are each formed with non-linear bent surfaces along the bent portions 111 of the core material 110.

Moreover, the first resin material 120 may additionally have an inorganic filler contained therein.

The second resin material 130 and the third resin material 150 are laminated, respectively, above and below the core material 110 having the first resin material 120 impregnated therein in such a way that one surface of the second resin material 130 and one surface of the third resin material 150 are in contact with the non-linear bent surfaces of the core material 110. Accordingly, as shown in FIG. 2, a non-linear joint interface coupled with the first resin material 120 is formed between the core material 110 and the second and third resin materials 130, 150.

The resin constituting the first resin material 120 and the resin constituting the second and third resin materials 130, 150 may have different coefficients of thermal expansion from one another, and one of the second and third resin materials 130, 150 may be made of a resin having the same coefficient of thermal expansion as that of the first resin material 120.

Moreover, the second resin material 130 and the third resin material 150 may be formed with a same thickness such that the second resin material 130 and the third resin material 150 are symmetrical about the core material 110 when the prepreg 200 is manufactured.

Hereinafter, an example method of manufacturing a prepreg will be discussed. The following method of manufacturing a prepreg will be described using the example prepreg 200 in FIG. 2. The only difference in the method of manufacturing a prepreg 100 of the example illustrated in FIG. 1 is the kind of resin material laminated above and below the core material 110.

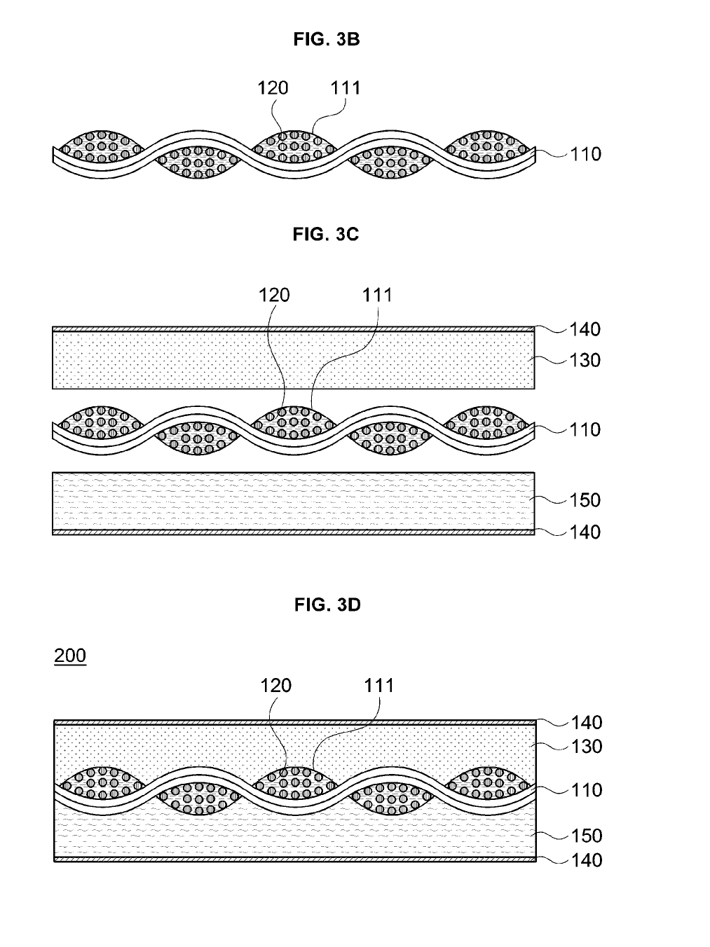

FIG. 3A to FIG. 3D show example processes of a method of manufacturing a prepreg 200, with FIGS. 3A and 3B being cross-sectional views showing the core material 110, FIG. 3C being a cross-sectional view showing the resin material 130 laminated above and below the core material, and FIG. 3D being a cross-sectional view showing the prepreg 200 in which the resin material 130 is laminated above the core material 110 and the resin material 150 is laminated below the core material 110.

As illustrated in FIG. 3A, first, a core material 110 of fabric cloth or glass cloth in which one to three rows of fabric or glass filaments are woven is prepared. As described above, the core material 110 is a woven object having bent portions 111, and may be formed by overlapping fabric or glass filaments on an upper surface and a lower surface thereof.

Then, as illustrated in FIG. 3A, a first resin material 120 is applied so as to cover the bent portions 111 of the core material 110. The first resin material 120 is impregnated in between the woven structure of the core material 110 and is hardened, while enveloping a surface of the core material 110, by thermosetting or UV curing (see FIG. 3B). The first resin material 120 is hardened along the bent portions 111 to form non-linear bent surfaces above and below the core material 110.

The first resin material 120 impregnated in the core material 110 may be hardened in a B-stage semi-hardened state or in a C-stage full-hardened state. In the case of maintaining the first resin material 120 in the semi-hardened state, the first resin material 120 may be fully hardened when another resin material is laminated and compressed thereon in a later process.

Next, as illustrated in FIG. 3C, a second resin material 130 and a third resin material 150 are laminated, respectively, on an upper surface and a lower surface of the core material 110 having the first resin material 120 impregnated therein. The second and third resin materials 130, 150 have a predetermined thickness of resin coated on a cover film 140, which is an insulation film or a copper foil, and may be coated in a B-stage semi-hardened state.

After laminating the second resin material 130 and the third resin material 150, respectively, above and below the core material 110 to form a resin laminate, heat and pressure are applied to this resin laminate to compress the resin laminate about the core material 110. The resin laminate is pressed using a pressing method such as V-press, V-press lamination or roll-press, and a predetermined amount of heat is applied while the resin laminate is pressed.

When the second resin material 130 and the third resin material 150 are tightly adhered to the core material 110 by thermos-compression, surfaces of the second and third resin materials 130, 150 joining the core material 110 have a phase change and are integrally coupled with the first resin material 120 (see FIG. 3D). Joint interfaces of the second and third resin materials 130, 150 joining the first resin material 120 form non-linear joint interfaces along the bent portions 111 of the core material 110. The non-linear joint interface between one resin and another may increase an area of joint between the laminated resins. Accordingly, when the core material 110 having the first resin material 120 impregnated therein is viewed from above, the bent portions 111 which form a number of protrusions are inserted into and joined with the second and third resin materials 130, 150, thereby preventing gaps or exfoliation in the prepreg 200.

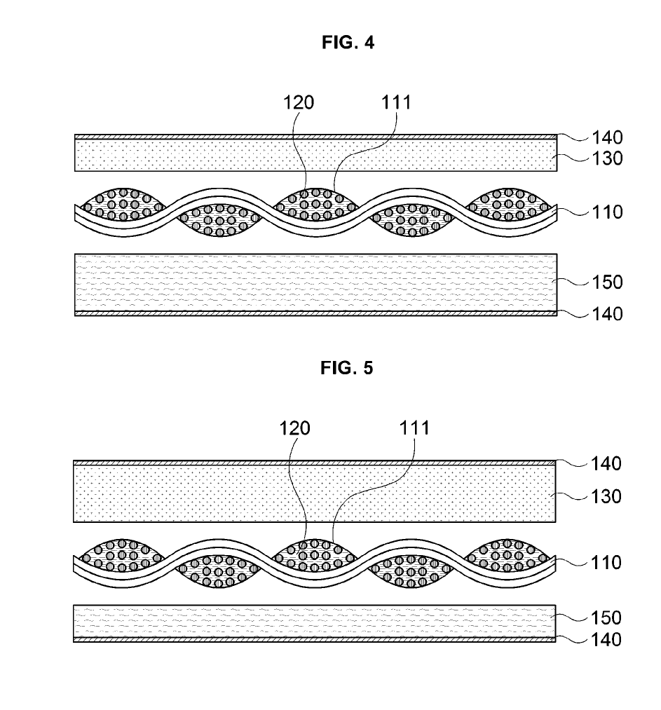

FIG. 4 and FIG. 5 show example processes of another method of manufacturing a prepreg, wherein FIG. 4 shows a process in which the second resin material 130 laminated on the core material 110 is thinner than the third resin material 150 laminated on the core material 110, and FIG. 5 shows a process in which the third resin material 150 laminated on the core material 110 is thinner than the second resin material 130 laminated on the core material 110.

As illustrated, during the laminating of the second resin material 130 and the third resin material 150, respectively, above and below the core material 110 having a first resin material 120 impregnated therein, the second resin material 130 and the third resin material 150 have different thicknesses from each other.

Specifically, as shown in FIG. 4, the second resin material 130 laminated above the core material 110 is formed to be thinner than the third resin material 150 laminated below the core material 110.

Alternatively, as illustrated in FIG. 5, the third resin material 150 laminated below the core material 110 is formed to be thinner than the second resin material 130 laminated above the core material 110.

Once the second resin material 130 and the third resin material 150 are laminated above and below the core material 110, respectively, heat and pressure are applied to compress this resin laminate about the core material 110 through a pressing method such as V-press, V-press lamination or roll-press, as described with reference to FIG. 3.

By forming one of the second and third resin materials 130, 150 to be thinner than the other, as illustrated in FIGS. 4 and 5, it is possible to manufacture a thin prepreg when different types of resin material are laminated about the core material 110.

Moreover, as the second and third resin materials 130, 150 form a non-linear joint interface with and are laminated on the first resin material 120 impregnated in the core material 110, the prepreg manufactured through the method illustrated in FIGS. 4 and 5 may have a circuit formed on a surface of the thinner one of the two resin materials that is laminated on one surface of the core material 110, and may have a resin-buried circuit pattern formed on the thicker one of the two resin materials that is laminated on the other surface of the core material 110.

Accordingly, the example prepregs disclosed herein may have a smaller thickness of resin material laminated about the core material 110, and may have circuit patterns formed on a surface of the resin material and buried in the resin material, making it possible to manufacture a thin printed circuit board.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A prepreg comprising:
a core material having a first resin material impregnated therein; and
second resin materials laminated above and below the core material and comprising a non-linear joint interface formed with the first resin material.

2. The prepreg of claim 1, wherein the core material comprises a bent portion, and the first resin material is hardened along the bent portion such that an upper surface and a lower surface of the core material are formed as bent surfaces.

3. The prepreg of claim 1, wherein the core material comprises fabric cloth or glass cloth.

4. The prepreg of claim 1, wherein the first resin material comprises an inorganic filler.

5. The prepreg of claim 1, wherein the second resin materials are formed in a same thickness above and below the core material, and have same material properties.

6. A prepreg comprising:
a core material having a first resin material impregnated therein;
a second resin material laminated above the core material; and
a third resin material laminated below the core material,
wherein at least one of the second resin material or the third resin material forms a non-linear joint interface at a surface joined with the first resin material.

7. The prepreg of claim 6, wherein the core material comprises a bent portion formed thereon, and the first resin material is hardened along the bent portion such that an upper surface and a lower surface of the core material are formed as bent surfaces.

8. The prepreg of claim 6, wherein the first resin material comprises an inorganic filler.

9. The prepreg of claim 6, wherein the second resin material and the third resin material have different material properties and different coefficients of thermal expansion from each other.

10. The prepreg of claim 9, wherein the second resin material or the third resin material has material properties that are the same as material properties of the first resin material and a coefficient of thermal expansion that is the same as a coefficient of thermal expansion of the first resin material.

11. The prepreg of claim 6, wherein the second resin material and the third resin material have a same thickness.

12. The prepreg of claim 6, wherein the second resin material and the third resin material have different thicknesses from each other.

13. The prepreg of claim 12, wherein the second resin material is thinner than the third resin material.

14. The prepreg of claim 13, wherein a circuit is formed on a surface of the second resin material, and a buried circuit pattern is formed on the third resin material.

15. The prepreg of claim 12, wherein the third resin material is thinner than the second resin material.

16. The prepreg of claim 15, wherein a circuit is formed on a surface of the third resin material, and a buried circuit pattern is formed on the second resin material.

17. A method of manufacturing a prepreg, comprising:
preparing a core material comprising fabric cloth or glass cloth;
applying a first resin material to cover a bent portion of the core material;
hardening the first resin material such that the first resin material forms a bent surface along the bent portion of the core material;
laminating a second resin material and a third resin material, respectively, above and below the core material; and
thermos-compressing the second resin material and the third resin material such that a non-linear joint interface is formed at a joint surface between the first resin material and at least one of the second resin material or the third resin material.

18. The method of claim 17, wherein in the hardening of the first resin material, the first resin material is semi-hardened or full-hardened.

19. The method of claim 17, wherein the laminating of the second resin material and the third resin material comprises applying the second resin material and the third resin material on respective cover films and maintaining the second resin material and the third resin material in a semi-hardened state.

20. The method of claim 19, wherein the second resin material and the third resin material have different material properties and different coefficients of thermal expansion from each other, and the laminating of the second resin material and the third resin material comprises laminating the second resin material and the third resin material in a same thickness.

21. The method of claim 19, wherein the second resin material and the third resin material have different material properties and different coefficients of thermal expansion from each other, and the laminating of the second resin material and the third resin material comprises laminating the second resin material and the third resin material in different thicknesses from each other.

22. The method of claim 21, wherein the thickness of the third resin material is less than the thickness of the second resin material.

23. The method of claim 21, wherein the thickness of the second resin material is less than the thickness of the third resin material.
